(19) United States
(12) Patent Application Publication
(10) Pub. No.: US 2007/0259515 A1
(43) Pub. Date: Nov. 8, 2007

(54) METHOD FOR MANUFACTURING WAFER-LEVEL PACKAGES FOR FLIP CHIPS CAPABLE OF PREVENTING ADHESIVES FROM ABSORBING WATER

(75) Inventors: Kyung-Wook Paik, Daejeon (KR); Ho-Young Son, Daejeon (KR)

Correspondence Address: METCALF INTELLECTUAL PROPERTY LAW, LLC, 2795 EAST COTTONWOOD PARKWAY, SUITE 155, SALT LAKE CITY, UT, 84121, US

(73) Assignee: KOREA ADVANCED INSTITUTE OF SCIENCE AND TECHNOLOGY, Daejeon (KR)

(21) Appl. No.: 11/744,096

(22) Filed: May 3, 2007

(30) Foreign Application Priority Data
May 4, 2006 (KR) 10-2006-0040470

(51) Int. Cl. H01L 21/44; H01L 21/00

(52) U.S. Cl. 438/612; 438/118

(57) ABSTRACT

The present invention provides a method for manufacturing a wafer-level package comprising the steps of coating adhesives on a wafer on which bumps are already formed and irradiating the adhesive layer using a laser to divide the wafer into individual chip units. According to the present invention, it is possible to effectively prevent adhesives from absorbing water during the dicing process when manufacturing a wafer-level package.

### RELATED APPLICATIONS

This application claims the benefit of Korean Patent Application No. 10-2006-0040470, filed May 4, 2006, and is incorporated herein.

### BACKGROUND OF THE INVENTION

1. Field of the Invention

The present invention relates, generally, to a method for manufacturing a wafer-level package and more specifically, to a new method for manufacturing a wafer-level package capable of effectively preventing adhesives from absorbing water during the dicing process when manufacturing a wafer-level package.

2. Description of the Related Art

An Electronic packaging technology is a very important technology in determining the capacity, size, price, and reliability of a final electronic product; recently, its importance is recognized in accordance with its tendency to achieve good electric performance and miniaturization. Among the electronic packaging technologies, anisotropic conductive adhesives used as bonding materials for mounting a chip on a substrate are used in a variety of areas: not only as a bonding material for chips used to drive LCDs, but also as a bonding material for chips in a semiconductor package.

Especially, chip bonding methods for a flip chip in a semiconductor package can be generally divided into either a solder flip chip using solder bumps or a non-solder flip chip using non-solder bumps and anisotropic conductive adhesives. The conventional solder flip chip bonding technology uses complicated processes such as coating the solder flux, aligning the chip and substrate, reflowing the solder, removing the flux, underfill dispensing and curing, and it is disadvantageous because the manufacturing cost is increased. However, the flip chip bonding technology using a non-solder bump and anisotropic conductive adhesives is recognized as an important technology due to its many benefits. When compared with the solder flip chip technology, this process is simpler, lead-free, environmentally friendly fluxless, low temperature, ultra fine pitch adaptable, and so on. Furthermore, it can be applied to a rigid, board-like organic substrates and glass or flexible substrates in various shapes such as chip-on-board (COB), chip-on-glass (COG), and chip-on-flex (COF).

The conventional flip chip using anisotropic conductive adhesives is manufactured in a single chip package and employs a method where the anisotropic conductive adhesive is cut to a size similar as that of the chip and then pre-laminated on the substrate. Next, the individually diced chips where the bumps are formed are aligned; then heat and pressure are applied to bond the flip chip.

FIG. 1 shows schematically the method for manufacturing a wafer-type flip chip using anisotropic conductive adhesives, which are pre-coated on the wafer using the methods provided in Korean Patent No. 361640 entitled “A method for manufacturing a wafer-type flip chip using coated anisotropic conductive adhesives” and U.S. Pat. No. 6,518,097 entitled “Method for fabricating wafer-level flip chip packages using pre-coated anisotropic conductive adhesives”.

The method for bonding a wafer-level flip chip can be divided into three steps: 1) coating anisotropic conductive adhesives onto the film, paste, or non-conductive adhesives on the wafer on which the non-solder bumps are formed by lamination or spin coating; 2) dicing the wafer coated by the adhesives into individual chips; and, 3) flip chip bonding the chip coated by adhesives and individually diced to a substrate.

As described above, the method for manufacturing a wafer-level package according to conventional technologies is limited when the anisotropic conductive adhesives or non-conductive adhesives absorb water during the dicing process, where the wafer coated with anisotropic conductive adhesives is diced into individual chips, as a result of the cooling water used to cool the diamond blade wheel which rotates quickly at speeds from ten to hundreds of thousands rpm.

If a small amount of water is included in the adhesives in the manufacturing process for a package, it exists in the shape of voids or bubbles in the adhesives, even after the bonding is completed, and it causes delamination at the adhesives/substrate or adhesives/chip interfaces. This degrades the quality of the chip and furthermore, the voids or bubbles grow due to the external moisture in the water-absorbing environment, resulting in a problem fatally affecting the reliability of the water absorption in a package.

### SUMMARY OF THE INVENTION

The present invention has been designed keeping in mind the above problems that occur in the related art, and the object of the present invention is to provide a new method for manufacturing a wafer-level package that can effectively prevent the adhesives from absorbing water during the dicing process when manufacturing a wafer-level package.

In order to obtain the above object, the present invention provides a method for manufacturing a wafer-level package comprising the steps of coating adhesives on the wafer on which bumps are formed and irradiating the adhesive layer using a laser to divide the wafer into individual chip units.

The present invention can further comprises the step of dicing the wafer on which the bumps are formed into individual chips before coating the adhesives.

The present invention can further comprises the step of removing the water contained in the adhesives by drying the wafer after it has been divided into individual chips.

The present invention provides a method for manufacturing a wafer-level package characterized by the drying step no longer being performed when the curing of the adhesives exceeds 30%.

The present invention provides a method for manufacturing a wafer-level package of which the adhesives are anisotropic conductive adhesives or non-conductive adhesives.

The present invention provides a method for manufacturing a wafer-level package where the laser source is selected from a YAG laser, excimer laser, ultraviolet ray laser, or CO₂ laser.

The present invention provides a method for manufacturing a wafer-level package which dices a wafer using a laser source when the thickness of wafer is less than 200 μm.

### BRIEF DESCRIPTION OF THE DRAWINGS

FIG. 1 is a schematic view showing the process for manufacturing a wafer-level package for a conventional flip chip.

FIG. 2 is a graph depicting the amount of water absorbed according to the drying time and the degree of cure. It also shows that the water absorbed during dicing can be removed by additional drying after the dicing is completed and the water included in the anisotropic conductive adhesives or non-conductive adhesives or the residual solvent can be removed using the present invention.

FIG. 3 is a schematic view showing the process where anisotropic conductive adhesives or non-conductive adhesives are coated on the pre-diced wafer and cut by a laser, which is a preferred embodiment of the present invention.

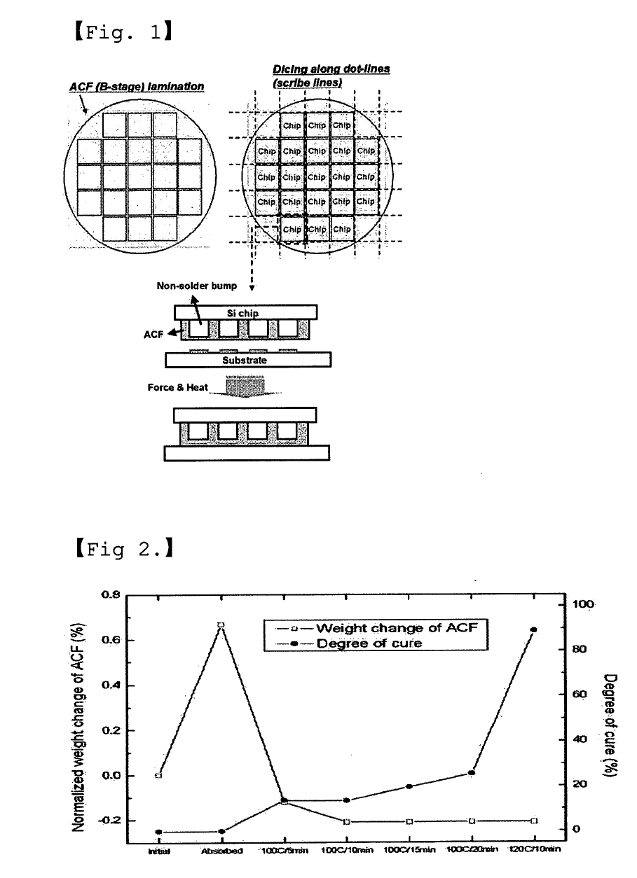

### DETAILED DESCRIPTION OF THE INVENTION

Hereinafter, the present invention will be described in detail.

The present invention provides a method to prevent water absorption into the adhesives during the dicing process in the manufacturing of conventional wafer-level packages using pre-applied adhesives.

For this, the method for manufacturing a wafer-level package according to the present invention comprises coating the adhesives onto a wafer on which bumps are formed and irradiating the adhesive layer using a laser to divide the wafer into individual chip units.

Herein, bump means a non-solder bump.

The usable adhesives in the present invention are not restricted, but a thermoplastic resin or thermosetting resin can be used. An example of a thermoplastic resin is a solid phenoxy resin and an example of a thermosetting resin is an epoxy resin of solid bisphenol A-type, an epoxy resin of liquid bisphenol F type, or a blend of these resins.

The usable adhesives in the present invention include conductive and non-conductive adhesives. The conductive adhesives include isotropic or anisotropic adhesives, but anisotropic conductive adhesives are preferred.

The conductive adhesives include conductive balls in the composition and are not specifically limited but are preferably polymer balls thinly coated with a nickel/metal layer, nickel powders, or silver powders alloyed with gold. The content in the composition of these conductive balls is not specifically limited, but it is sufficient to select a ball with a diameter of 2 to 10 μm and add them from 10 to 60 wt % in the polymer resin.

Moreover, the adhesives used in the present invention may include non-conductive particles. The non-conductive particles are not limited, but alumina, beryllia, silica carbide, or silica powder is preferred. The content in the composition of the non-conductive particles is not limited, but it is adequate to select a particle with a diameter of 0.1 to 1.0 μm and add them from 10 to 60 wt % in the total composition.

The adhesives used in the present invention may comprise proper organic solvents and a curing agent. Examples of a solvent comprise methylethylketone, toluene, or their mixed solvent, and an example of a curing agent is a liquid imidazole curing agent.

The adhesives coated on the wafer may be a film or a paste type. If the adhesives are a film type, the adhesives can be pre-coated on a wafer at 5 kgf/cm². If the adhesives are a paste type, it is possible to coat the adhesives in a specific amount in a desired shape using a method such as a spin coating, dispensing, doctor blade, meniscus coating, and so on.

According to the present invention, the adhesives can be coated before or after dicing the wafer into individual chips with a laser. The compatible laser in the present invention is not limited; for example, a YAG laser, excimer laser, ultraviolet laser, or CO₂ laser may be used. If an adhesive-coated wafer is divided into individual chips using a laser, the thickness of the wafer itself should be considered when choosing the most appropriate laser. In general, when the thickness of the wafer exceeds 200 μm, it is unreasonable to dice the adhesives layer together with the wafer. In this situation, it is preferable to dice the wafer into individual chips along a scribing line prior to coating the adhesives. Therefore, to only dice the adhesives layer into individual chips along the scribing line can prevent heat from being generated. Because a laser is used, heat is not generated during the dicing, and thus, cooling water is not required. Therefore, it is possible to prevent water from being absorbed by the adhesives.

Next, after dividing the wafer and adhesives layer into individual chips, heat and pressure are applied to the substrate to perform flip chip bonding for chip-on-board (COB), chip-on-glass (COG), and chip-on-flex (COF) shapes. Even in this case, it is preferable to comprise an additional drying process under the condition that the curing of the adhesives does not occur or occurs 30% or less in order to prevent water absorption into the adhesives.

A concrete embodiment to prevent water from being absorbed into the adhesives during the dicing process will be suggested.

According to the present invention, the amount of absorbed anisotropic conductive or non-conductive adhesive during the conventional dicing process was measured to be approximately 0.5 to 0.7 wt %. It is known that a relatively great amount of water is absorbed into the adhesives even though it is also dependent on the dicing process time, cooling water temperature, wheel velocity, and quantity.

As a result, three methods can be suggested to prevent water being absorbed into the adhesives and these methods are described more in detail as follows.

1. Method for Removing Water Absorbed in the Adhesives by Additional Drying after Dicing

The drying process can be performed directly after dicing is completed in order to remove the water absorbed in the adhesives during the dicing process. At this time, to adequately dry the absorbed water, a temperature as high as possible and drying time as long as possible are required, but this results in increasing the degree of cure of the adhesives. Because the adhesives are to be bonded to a substrate in the next fabrication step, if some portion of the adhesives is cured before bonding, it has a serious effect on the flow of the resin during the bonding, degrading the bonding characteristics and reliability. Therefore, it is important to dry the adhesives at a temperature as low as possible so that the adhesives are not cured but are only dried completely.

FIG. 2 is a graph showing the amount of water absorbed with the drying time and degree of cure where anisotropic conductive or non-conductive adhesives coated on the wafer are dried for 20 minutes at 100° C. after dicing. As a result, it can be seen that the mass of the anisotropic conductive or non-conductive adhesives is almost saturated after 10 minutes at 100° C., indicating that even if the adhesives are only dried for 10 minutes at 100° C., it is adequately dried. However, the degree of cure has a comparatively low value of approximately 10% after 10 minutes at 100° C., but the degree of cure continued to increase after 10 minutes. It is not preferable to dry the adhesives for 10 minutes at 120° C. because the degree of cure reached is 90%.

The more remarkable fact is that the initial weight of the anisotropic conductive or non-conductive adhesives after drying for five minutes at 100° C. is decreased by approximately 0.12 wt % when compared with the initial weight. It is considered that this change in weight results from the water that was absorbed in the anisotropic conductive adhesives and solvents which may have existed immediately after manufacture. Therefore, even if the anisotropic conductive adhesives do not absorb water during dicing, the drying process removes the absorbed moisture through additional drying. Accordingly, the drying process is expected to improve the reliability of absorbing water from a package.

As described above, it is a concern that the processing time increases due to the additional drying step when compared with the method suggested in the existing patents, but the time consumed for drying does not affect the entire processing time significantly and is negligible in comparison with the effect of removing latent water in the early stages through drying.

2. Method for Coating Film-Type Adhesives on a Pre-Diced Wafer and Cutting Anisotropic Conductive or Non-Conductive Adhesives by Laser

The conventional dicing technology employing a diamond blade wheel needs to use cooling water and it is unavoidable that the adhesives absorb water. The method for processing by laser is advantageous in that damage to the material can be minimized and the laser used for this purpose can be a YAG laser, excimer laser, ultraviolet laser, or CO₂ laser. The laser processing does not require a cooling water, therefore, water absorption is not a concern. The adhesives have a very thin thickness of 20 to 80 μm; this is advantageous because the time needed for processing and cutting by laser is very short. In addition, the dicing technology using a diamond blade wheel currently has a minimum cutting width of 40 μm, but it is possible to perform the process so that a smaller thickness is achieved. Therefore, the size of the adhesives coated on the chip can be controlled. When the adhesives are formed to be slightly larger than the chip, it is helpful to form an adequate fillet when bonding the substrate.

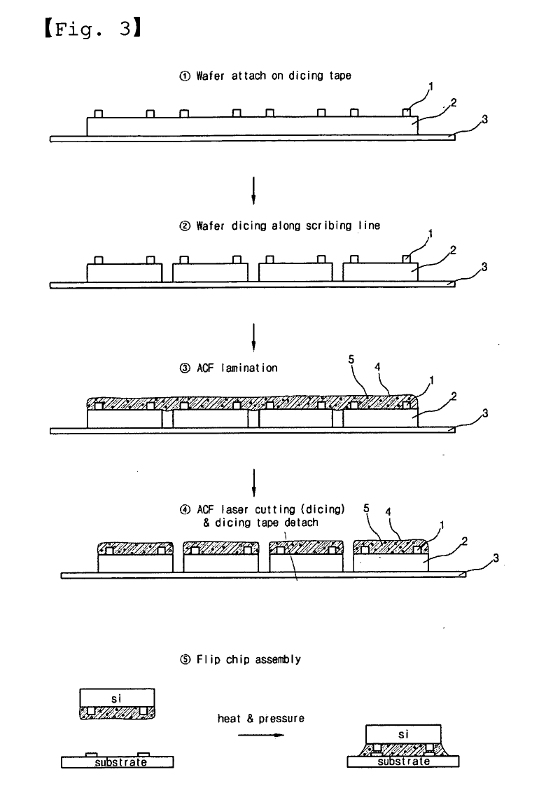

FIG. 3 is a schematic view of the processes where a wafer is diced first and then the adhesives are coated to divide the wafer into individual chips.

The process for bonding a wafer-level package using the above processes is divided into □ dicing the wafer (2) on which the bumps (1) are formed into individual chips along a scribing line (steps □→□); □ coating the adhesives (4) in the desired film on the wafer diced into individual chips (steps □→□); □ cutting the adhesives along the scribing lines in step □ using a laser source (steps □→□); and □ bonding individual chips on a substrate (steps □→□). Herein, the unexplained sign (3) refers to the dicing attaching tape (or dicing tape) and (5) refers to a conductive ball.

3. Method for Coating Adhesives on a Processed Thin Film Wafer (Less than 200 μm) and Cutting the Adhesives and Entire Wafer Using a Laser Dicing Method

Silicon wafers with a size of 4″ to 8″ have thicknesses of 500 to 750 μm when manufactured, but they are thinned to have a very thin thickness in a real package to decrease the thickness of the package and easily emit heat.

Meanwhile, the laser dicing technology employing a laser beam condensed using a convex lens does not need cooling water and, thus, can be applied in processing devices that have a low tolerance for water. In addition, this technology is advantageous in that the section width can be very small (approximately 5 to 10 μm) compared with the dicing method that uses a diamond blade wheel, and the section is clear-cut. Therefore, this technology has recently drawn attention due to its advantages. However, this technology is currently disadvantageous because it can only be applied when the thickness of the wafer is less than 200 μm. If a wafer is thick, dicing is not completed after one time and the feed speed of the beam slows. Accordingly, a wafer-level package using adhesives that require the thickness of the chip to be less than 200 μm can use the laser dicing method to dice the adhesives on a pre-coated wafer into individual chips.

This method can be explained in four steps: 1) thinning the wafer on which bumps are formed to ensure that it is less than 200 μm thick; 2) pre-coating the adhesives in a film or paste onto the wafer; 3) dicing the adhesives or the wafer into individual chips using a laser dicing method; and 4) bonding the individual chips onto a substrate.

Manufacturing a wafer-level package using anisotropic conductive adhesives or non-conductive adhesives in the above method can effectively prevent adhesives from absorbing water during dicing. As a result, according to the present invention, the method for manufacturing a wafer-level package is expected to not only reduce the number of processes and manufacturing costs, but also greatly improve the reliability of the device in a package and the characteristics.

What is claimed is:

1. A method for manufacturing a wafer-level package comprising the steps of:
coating adhesives on a wafer on which bumps are formed; and
irradiating the adhesive layer using a laser to divide the wafer into individual chip units.

2. The method as in claim 1, further comprising the step of dicing the wafer on which the bumps are formed into individual chips before the coating of the adhesives.

3. The method as in claim 1 further comprising the step of removing the water contained in the adhesives by drying the wafer after division into individual chips.

4. The method as in claim 3 wherein the drying step is no longer performed when the curing of the adhesives exceeds 30%.

5. The method as in claim 1, wherein the adhesives are anisotropic conductive adhesives or non-conductive adhesives.

6. The method as in claim 1, wherein the laser source is selected from a YAG laser, excimer laser, ultraviolet ray laser, and CO₂ laser.

7. The method as in claim 1, wherein the wafer is a thin film wafer with a thickness of less than 200 μm.
